(19) United States
(12) Patent Application Publication
(10) Pub. No.: US 2011/0240354 A1
(43) Pub. Date: Oct. 6, 2011

(54) WIRING BOARD AND METHOD FOR MANUFACTURING WIRING BOARD

(75) Inventors: Naoki FURUHATA, Ogaki-shi (JP); Shunsuke Sakai, Ogaki-shi (JP); Yukinobu Mikado, Ogaki-shi (JP)

(73) Assignee: IBIDEN CO., LTD., Ogaki-shi (JP)

(21) Appl. No.: 13/075,480

(22) Filed: Mar. 30, 2011

(30) Foreign Application Priority Data
Mar. 31, 2010 (JP) 2010-084539

(51) Int. Cl. H05K 1/16; H05K 1/00; H05K 3/36

(52) U.S. Cl. 174/258; 174/260; 29/830

(57) ABSTRACT

A wiring board including a substrate having a cavity, an electronic component accommodated in the cavity of the substrate, a first conductive pattern formed on a surface of the substrate and having a frame shape surrounding the opening of the cavity, a second conductive pattern formed on the surface of the substrate and outside the frame shape of the first conductive pattern, and an insulation layer formed on the surface of the substrate and covering the first conductive pattern, the second conductive pattern and the opening of the cavity. The first conductive pattern has a slit extending from the outside of the frame shape to the inside of the frame shape.

### CROSS-REFERENCE TO RELATED APPLICATIONS

The present application is based upon and claims the benefit of priority from the prior Japanese Patent Application No. 2010-084539, filed Mar. 31, 2010, the entire contents of which are hereby incorporated by reference.

### BACKGROUND OF THE INVENTION

1. Field of the Invention

The present invention relates to a wiring board and a method for manufacturing a wiring board.

2. Discussion of the Background

In recent years, as electronic devices with higher performance and smaller size have been developed. Technologies for accommodating electronic components such as an IC chip in a wiring board are described in Japanese Laid-Open Patent Publication Nos. 2002-246757 and 2001-332863. Using such technologies, terminals of a semiconductor element and wiring in a buildup layer are appropriately connected. The contents of Japanese Laid-Open Patent Publication Nos. 2002-246757 and 2001-332863 are incorporated herein by reference in their entirety in this application.

### SUMMARY OF THE INVENTION

According to one aspect of the present invention, a wiring board includes a substrate having a cavity, an electronic component accommodated in the cavity of the substrate, a first conductive pattern formed on a surface of the substrate and having a frame shape surrounding the opening of the cavity, a second conductive pattern formed on the surface of the substrate and outside the frame shape of the first conductive pattern, and an insulation layer formed on the surface of the substrate and covering the first conductive pattern, the second conductive pattern and the opening of the cavity. The first conductive pattern has a slit extending from the outside of the frame shape to the inside of the frame shape.

According to another aspect of the present invention, a method for manufacturing a wiring board includes forming in a substrate a cavity which accommodates an electronic component, forming on a surface of the substrate a first conductive pattern having a frame shape surrounding the opening of the cavity and a slit extending from the outside of the frame shape to the inside of the frame shape, forming a second conductive pattern on the surface of the substrate outside the frame shape of the first conductive pattern, accommodating in the cavity of the substrate an electronic component, and forming on the surface an insulation layer covering the first conductive pattern, the second conductive pattern and the opening of the cavity.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically showing a wiring board with a built-in electronic component;

FIG. 2 is a view to illustrate a method for manufacturing a wiring board with a built-in electronic component;

FIG. 3 is a view to illustrate a method for manufacturing a wiring board with a built-in electronic component;

FIG. 4 is a view to illustrate a method for manufacturing a wiring board with a built-in electronic component;

FIG. 5 is a view to illustrate a method for manufacturing a wiring board with a built-in electronic component;

FIG. 6 is a view to illustrate a method for manufacturing a wiring board with a built-in electronic component;

FIG. 7 is a view to illustrate a method for manufacturing a wiring board with a built-in electronic component;

FIG. 8 is a view to illustrate a method for manufacturing a wiring board with a built-in electronic component;

FIG. 9 is a view to illustrate a method for manufacturing a wiring board with a built-in electronic component;

FIG. 10 is a view to illustrate a method for manufacturing a wiring board with a built-in electronic component;

FIG. 11 is a view to illustrate a method for manufacturing a wiring board with a built-in electronic component;

FIG. 12 is a view to illustrate a method for manufacturing a wiring board with a built-in electronic component;

FIG. 13 is a view to illustrate a method for manufacturing a wiring board with a built-in electronic component;

FIG. 14 is a view to illustrate a method for manufacturing a wiring board with a built-in electronic component;

FIG. 15 is a view to illustrate a method for manufacturing a wiring board with a built-in electronic component;

FIG. 16 is a view showing a buildup multilayer printed wiring board;

FIG. 17 is a view to illustrate a method for manufacturing a wiring board with a built-in electronic component according to a modified example;

FIG. 18 is a view to illustrate a method for manufacturing a wiring board with a built-in electronic component according to the modified example;

FIG. 19 is a view to illustrate a method for manufacturing a wiring board with a built-in electronic component according to the modified example;

FIG. 20 is a view to illustrate a method for manufacturing a wiring board with a built-in electronic component according to the modified example;

FIG. 21 is a view showing a modified example of a conductive pattern;

FIG. 22 is a view showing another modified example of a conductive pattern;

FIG. 23 is a view showing yet another modified example of a conductive pattern;

FIG. 24 is a view showing yet another modified example of a conductive pattern;

FIG. 25 is a view showing yet another modified example of a conductive pattern;

FIG. 26 is a view showing yet another modified example of a conductive pattern;

FIG. 27 is a view showing yet another modified example of a conductive pattern;

FIG. 28 is a view showing yet another modified example of a conductive pattern;

FIG. 29 is a view showing yet another modified example of a conductive pattern;

FIG. 30 is a view showing yet another modified example of a conductive pattern;

FIG. 31 is a view showing yet another modified example of a conductive pattern;

FIG. 32 is a view showing yet another modified example of a conductive pattern;

FIG. 33 is a view to illustrate a method for manufacturing a wiring board with a built-in electronic component according to a modified example;

FIG. 34 is a view to illustrate a method for manufacturing a wiring board with a built-in electronic component according to the modified example;

FIG. 35 is a view to illustrate a method for manufacturing a wiring board with a built-in electronic component according to the modified example;

FIG. 36 is a view to illustrate a method for manufacturing a wiring board with a built-in electronic component according to the modified example;

FIG. 37 is a view to illustrate a method for manufacturing a wiring board with a built-in electronic component according to the modified example;

FIG. 38 is a view to illustrate a method for manufacturing a wiring board with a built-in electronic component according to the modified example;

FIG. 39 is a view to illustrate a method for manufacturing a wiring board with a built-in electronic component according to another modified example;

FIG. 40 is a view to illustrate a method for manufacturing a wiring board with a built-in electronic component according to yet another modified example;

FIG. 41 is a view to illustrate a method for manufacturing a wiring board with a built-in electronic component according to the other modified example;

FIG. 42 is a view to illustrate a method for manufacturing a wiring board with a built-in electronic component according to the other modified example;

FIG. 43 is a view to illustrate a method for manufacturing a wiring board with a built-in electronic component according to the other modified example;

FIG. 44 is a view to illustrate a method for manufacturing a wiring board with a built-in electronic component according to yet another modified example;

FIG. 45 is a view to illustrate a method for manufacturing a wiring board with a built-in electronic component according to yet another modified example; and

FIG. 46 is a view showing a laminated wiring board.

### DETAILED DESCRIPTION OF THE EMBODIMENTS

The embodiments will now be described with reference to the accompanying drawings, wherein like reference numerals designate corresponding or identical elements throughout the various drawings.

A coordinate system of axis X, axis Y and axis Z, which are perpendicular to each other, is used in the description.

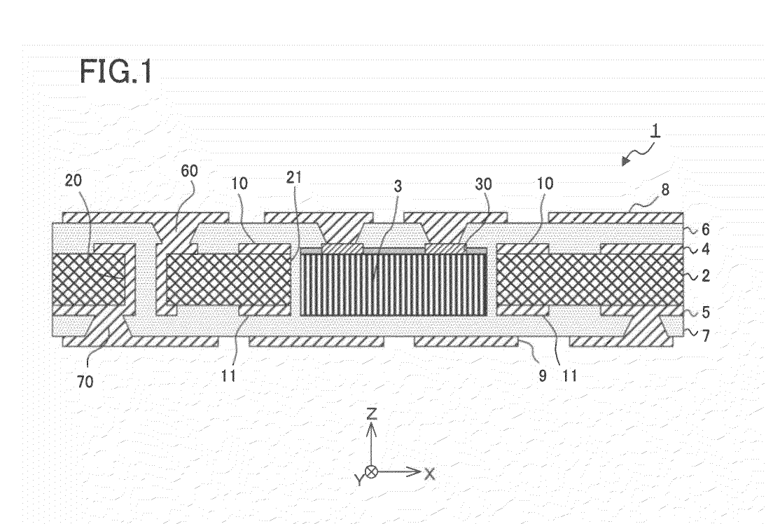

FIG. 1 is a cross-sectional view schematically showing wiring board 1 with a built-in electronic component according to the present embodiment. Wiring board 1 with a built-in electronic component has substrate 2, electronic component 3 accommodated in substrate 2, conductive patterns (4, 5) and interlayer insulation layers (6, 7) formed respectively on the upper and lower surfaces of substrate 2, conductive patterns (8, 9) formed respectively on the surfaces of interlayer insulation layers (6, 7), conductive pattern 10 formed on the upper surface of substrate 2 (the surface on the (+Z) side), and conductive pattern 11 formed on the lower surface of substrate 2 (the surface on the (−Z) side).

Substrate 2 is a substrate made by impregnating reinforcement material (base material) such as glass cloth, glass non-woven fabric, aramid non-woven fabric and the like with epoxy resin, BT (bismaleimide triazine) resin, polyimide resin or the like. Substrate 2 is approximately 110 μm thick, and cavity 21 in a rectangular shape is formed in the center. Cavity 21 is not always required to be positioned in the center of substrate 2.

Conductive patterns (4, 10) are formed on the upper surface of substrate 2, and conductive patterns (5, 11) are formed on the lower surface of substrate 2. Those conductive patterns (4, 5, 10, 11) are each approximately 20 μm thick.

Conductive patterns (4, 5) are each made of copper or the like, and are electrically connected by through-hole conductors 20. Conductive patterns (10, 11) are each formed to surround cavity 21. Conductive pattern 10 is used to prevent a recess from being formed along the cavity on the upper surface of interlayer insulation layer 6; a detailed description will be provided later. Also, conductive pattern 11 is used to precisely position electronic component 3.

Electronic component 3 is an IC chip. Electronic component 3 is accommodated in cavity 21 formed in substrate 2 in such a way that terminals 30 are positioned on the upper side.

Interlayer insulation layer 6 is formed to cover the upper surface of substrate 2. Interlayer insulation layer 6 is made of cured prepreg, for example, and is 60 μm thick. Conductive patterns (4, 10) formed on the upper surface of substrate 2 and conductive patterns 8 formed on the upper surface of interlayer insulation layer 6 are electrically insulated from each other by interlayer insulation layer 6.

Prepreg is formed, for example, by impregnating glass fiber or aramid fiber with epoxy resin, polyester resin, bismaleimide triazine resin (BT resin), imide resin (polyimide), phenol resin, allyl polyphenylene ether resin (A-PPE resin) or the like.

Interlayer insulation layer 7 is formed to cover the lower surface of substrate 2. Interlayer insulation layer 7 is made of cured prepreg, for example, and is 60 μm thick, the same as interlayer insulation layer 6. Conductive patterns (5, 11) formed on the lower surface of substrate 2 and conductive patterns 9 formed on the lower surface of interlayer insulation layer 7 are electrically insulated from each other by interlayer insulation layer 7.

Instead of prepreg, a liquid-type or film-type thermosetting resin or thermoplastic resin, or RCF (resin-coated copper foil) may also be used as the material for interlayer insulation layers (6, 7). Here, as for thermosetting resin, for example, epoxy resin, imide resin (polyimide), BT resin, allyl polyphenylene ether resin, aramid resin or the like may be used. Also, as for thermoplastic resin, for example, liquid-crystal polymer (LCP), PEEK resin, PTFE resin (fluororesin) or the like may be used. Such materials are preferred to be selected according to requirements, for example, from the viewpoints of insulation, dielectric properties, heat resistance, mechanical features and the like. In addition, additives such as curing agents, stabilizers, fillers and the like may be contained in the above resin.

Conductive patterns 8 are formed on the upper surface of interlayer insulation layer 6. Conductive patterns 8 are electrically connected to conductive patterns 4 and terminals 30 of electronic component 3 through via conductors 60.

Conductive patterns 9 are formed on the lower surface of interlayer insulation layer 7. Conductive patterns 9 are electrically connected to conductive patterns 5 through via conductors 70. Conductive patterns (8, 9) are made of copper or the like, and are each approximately 20 μm thick.

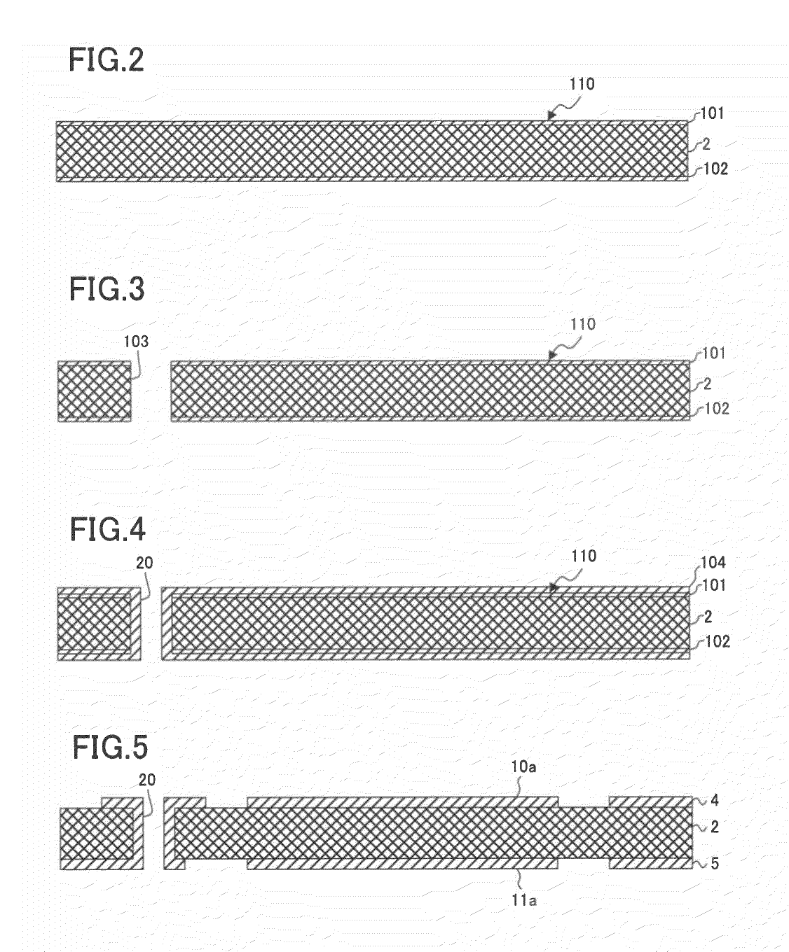

Next, a method for manufacturing wiring board 1 with a built-in electronic component is described with reference to FIGS. 2 through 14.

As shown in FIG. 2, copper-clad laminate 110 is prepared, being made of substrate 2 which is approximately 110 μm thick and of copper foils (101, 102) which are laminated on the surfaces of substrate 2 and are approximately 12 μm thick.

As shown in FIG. 3, through holes 103 are formed in copper-clad laminate 110 by using a drill or the like. A desmearing treatment is performed. Accordingly, smearing or the like remaining on the inner surfaces of through holes 103 is removed.

Electroless copper plating and electrolytic copper plating are performed on copper-clad laminate 110. Accordingly, as shown in FIG. 4, copper-plated film 104 is formed on the surfaces of copper-clad laminate 110 and on the inner-wall surfaces of through holes 103. Copper-plated film 104 formed on the inner-wall surfaces of through holes 103 becomes through-hole conductors 20.

By using a subtractive method, for example, copper foils (101, 102) and copper-plated film 104 on the surfaces of substrate 2 are patterned. Accordingly, conductive patterns (4, 5) and conductive patterns (10a, 11a) including conductive patterns (10, 11) shown in FIG. 1 are formed on the surfaces of substrate 2, as shown in FIG. 5.

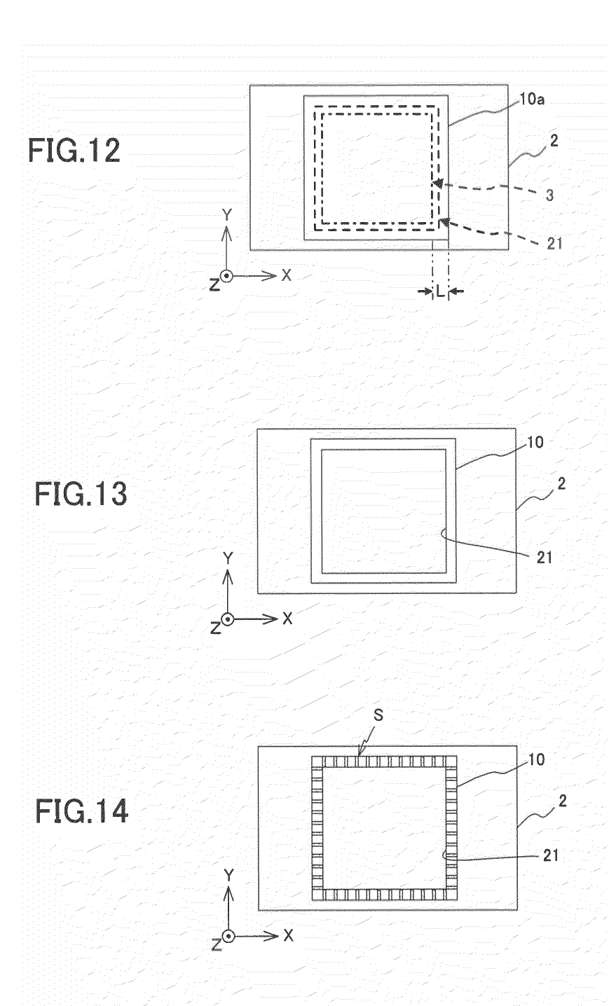

FIG. 12 is a view to illustrate the relationship between substrate 2 and conductive pattern (10a). As shown in FIG. 12, conductive pattern (10a) is formed to be greater than the area of the upper surface of electronic component 3. Specifically, the area of conductive pattern (10a) is equal to the area obtained by expanding the peripheral outline of electronic component 3 by predetermined length “L” (approximately 50 μm).

As shown in FIG. 5, conductive pattern (11a) is formed on the lower surface of substrate 2. The same as conductive pattern (10a), the area of conductive pattern (11a) is equal to the area obtained by expanding the peripheral outline of electronic component 3 by predetermined length “L” (approximately 50 μm).

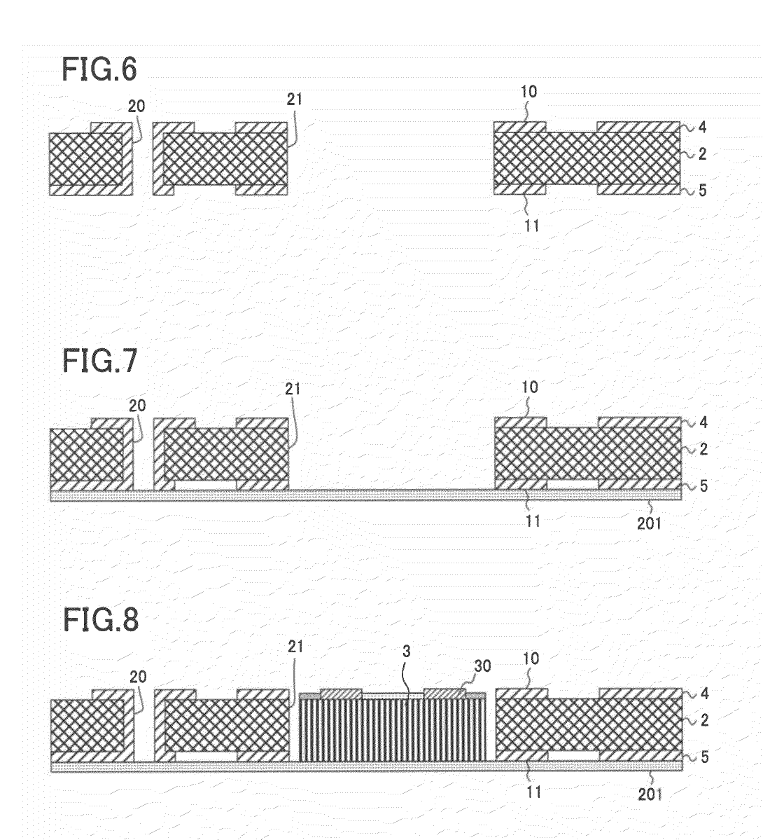

As shown in FIG. 6, cavity 21 to accommodate electronic component 3 is formed by using a drill or the like. The measurements of cavity 21 in directions of axis X and axis Y are set at approximately 8.1 mm. When cavity 21 is formed in substrate 2, conductive pattern (10a) is shaped to be a frame along the periphery of cavity 21 and becomes conductive pattern 10 as shown in FIG. 13.

When cavity 21 is formed in substrate 2, conductive pattern (11a) is also shaped to be a frame along the periphery of cavity 21 and becomes conductive pattern 11.

As shown in FIG. 14, multiple slits “S,” which extend from the outer side of conductive pattern 10 to the inner side, are formed in conductive pattern 10 by etching. The depth of slits “S” is substantially the same as the thickness of conductive pattern 10. Also, an example is as follows: when the entire area of conductive pattern 10 is set as (S1) and the area of conductive pattern 10 where slits “S” are formed is set as (S2), slits “S” are formed in conductive pattern 10 so that (S1)/(S2) is 0.1˜0.5.

Tape 201 is laminated on the lower-surface side of substrate 2 as shown in FIG. 7. As for tape 201, a UV tape whose adhesiveness decreases when irradiated by ultraviolet rays so as to be removed easily (such as the Adwill D series made by Lintec Corporation) may be used. Here, various adhesive tapes whose adhesiveness does not decrease even at high temperatures of 80° C. or greater during the preliminary curing process, for example, polyimide tapes or the like, may also be used.

During that time, since there is conductive pattern 11 which has the same thickness as that of conductive patterns 5 and is formed along the periphery of cavity 21, tape 201 is laminated substantially horizontally without warping.

Electronic component 3 is positioned on the upper surface of tape 201 (adhesive surface) with terminals 30 positioned on the upper side as shown in FIG. 8. Here, as described above, since tape 201 is set substantially horizontal, electronic component 3 is positioned without being shifted vertically away from substrate 2. Also, the measurement of electronic component 3 from its lower surface to the upper surfaces of terminals 30 is substantially the same as the measurement from the lower surface of conductive pattern 11 to the upper surface of conductive pattern 10. Accordingly, when electronic component 3 is placed on the upper surface of tape 201, the positions of the upper surfaces of terminals 30 are substantially the same as the position of the upper surface of conductive pattern 10.

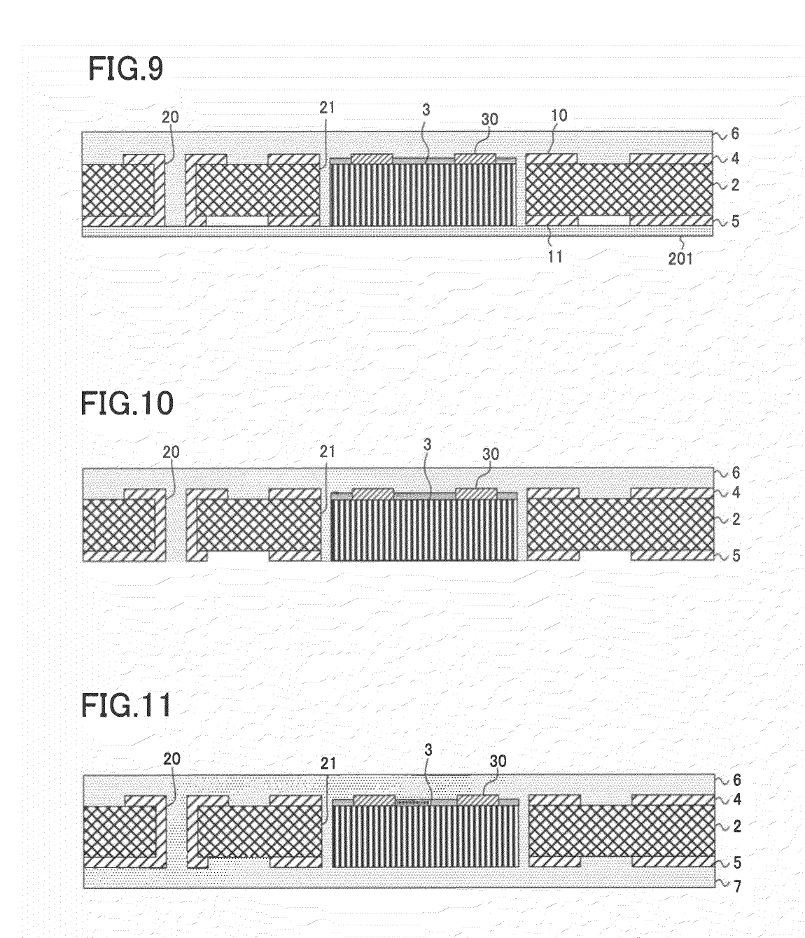

As shown in FIG. 9, film-type prepreg with an approximate thickness of 60 μm is laminated on the upper surface of substrate 2 using a vacuum lamination method. Accordingly, interlayer insulation layer 6 is formed.

During the lamination, resin that forms the prepreg is filled in through-hole conductors 20. Also, resin that forms the prepreg flows into the space in cavity 21 between electronic component 3 and the inner walls of substrate 2. Accordingly, the space between electronic component 3 and the inner walls of substrate 2 is filled with resin material.

The resin that has flowed into the space between electronic component 3 and the inner walls of substrate 2 is resin mainly from the prepreg positioned above electronic component 3. During the lamination, part of the resin outside conductive pattern 10 moves toward the portion surrounded by conductive pattern 10 through slits “S” formed in conductive pattern 10.

Furthermore, conductive pattern 11 is formed on the lower surface of substrate 2 to surround cavity 21. In addition, the lower surface of conductive pattern 11 is adhered to tape 201. Therefore, the resin that has flowed into the space between electronic component 3 and the inner walls of substrate 2 does not flow out to the lower-surface side of substrate 2, since conductive pattern 10 works as a wall to prevent such outflow.

As shown in FIG. 10, tape 201 is removed by irradiating ultraviolet rays at tape 201. As shown in FIG. 11, film-type prepreg with an approximate thickness of 60 μm is laminated to the lower surface of substrate 2 using a vacuum lamination method. Accordingly, interlayer insulation layer 7 is formed on the lower surface of substrate 2. In addition, resin that forms the prepreg flows into through-hole conductors 20 during the lamination.

Using a carbon dioxide gas (CO2) laser, a UV-YAG laser or the like, via holes are formed in interlayer insulation layers (6, 7). Conductive patterns (8, 9) and via conductors (60, 70) are formed by an additive method, for example. Accordingly, wiring board 1 with a built-in electronic component is completed as shown in FIG. 1.

As described so far, conductive pattern 10 is formed on the upper surface of substrate 2 to surround cavity 21 in the present embodiment. As shown in FIG. 9, for example, the position of the upper surface of conductive pattern 10 is substantially the same as the positions of terminals 30 formed in cavity 21. Accordingly, interlayer insulation layer 6 between conductive patterns 4 and terminals 30 does not warp to protrude downward, and a recess does not occur on the upper surface of interlayer insulation layer 6.

In the present embodiment, when interlayer insulation layer 6 is formed on the upper surface of substrate 2 by laminating film-type prepreg, resin mainly from the prepreg positioned above electronic component 3 flows into the space in cavity 21 between electronic component 3 and the inner walls of substrate 2. Part of the resin outside conductive pattern 10 moves to the portion surrounded by conductive pattern 10 through slits “S” formed in conductive pattern 10 as shown in FIG. 14. Therefore, the thickness of interlayer insulation layer 6 becomes uniform near the periphery of cavity 21. Accordingly, the upper surface of interlayer insulation layer 6 is made flat, enabling precise buildup of multiple conductive patterns and multiple interlayer insulation layers on substrate 2.

In the present embodiment, slits “S” are formed in the entire conductive pattern 10 as shown in FIG. 14. Therefore, the resin outside conductive pattern 10 moves uniformly to the portion surrounded by conductive pattern 10. Accordingly, the upper surface of interlayer insulation layer 6 is made flat, enabling precise buildup of multiple conductive patterns and multiple interlayer insulation layers on substrate 2. Also, resin is filled well between electronic component 3 and the inner walls of cavity 21.

In the present embodiment, conductive pattern 11 is formed on the lower surface of substrate 2 to surround cavity 21. In addition, the lower surface of conductive pattern 11 is adhered to tape 201. Accordingly, the resin that has flowed into the space between electronic component 3 and the inner walls of substrate 2 does not flow out toward the lower-surface side of substrate 2 since the resin is blocked by conductive pattern 10. Therefore, more resin than necessary does not flow out from interlayer insulation layer 6 positioned on the portion surrounded by conductive pattern 10. Thus, a recess does not occur on the upper surface of interlayer insulation layer 6. Accordingly, the upper surface of interlayer insulation layer 6 is made flat, enabling precise buildup of multiple conductive patterns and multiple interlayer insulation layers on substrate 2.

In the present embodiment, electronic component 3 is maintained substantially horizontally in cavity 21 because of tape 201 laminated substantially horizontally. Therefore, surface flatness of interlayer insulation layer 6 is ensured. As a result, fine conductive patterns 8 are formed on interlayer insulation layer 6. Also, via conductors are formed precisely. Accordingly, connection reliability increases between terminals 30 of electronic component 3 and via conductors 60.

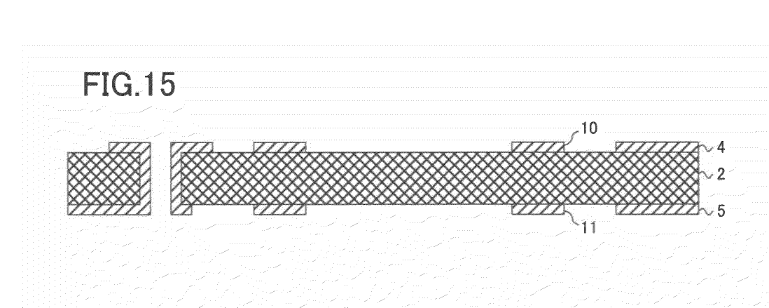

In the present embodiment, when cavity 21 is formed in substrate 2, conductive patterns (10a, 11a) are each shaped to be a frame along the periphery of cavity 21 and become conductive patterns (10, 11) as shown in FIG. 13. However, the present embodiment is not limited to such, and as shown in FIG. 15, conductive patterns (10, 11) may also be formed in advance before cavity 21 is formed. In such a case, conductive patterns (10, 11) are preferred to be formed as well during the step when conductive patterns (4, 5) are formed. In addition, slits “S” may also be formed during that same step.

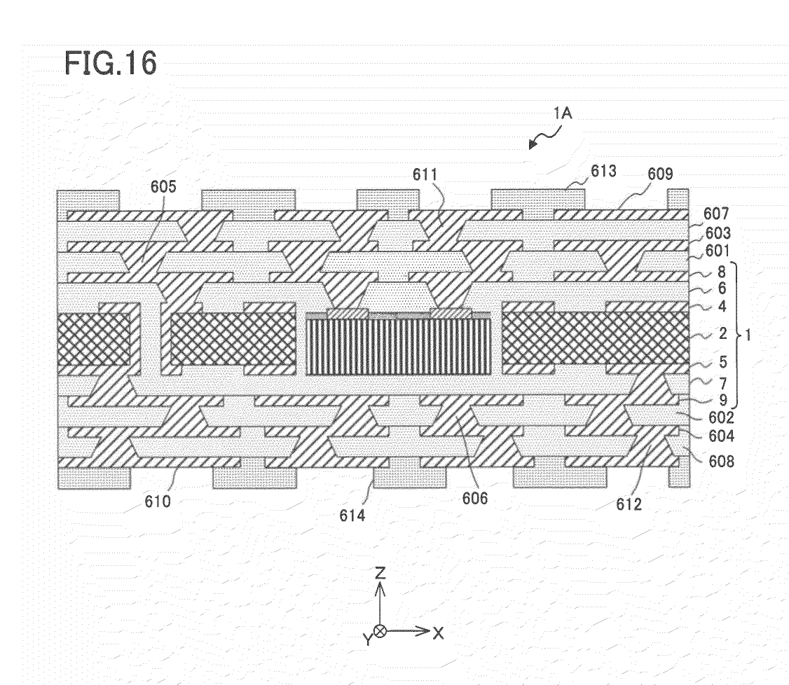

FIG. 16 is a view showing buildup multilayer printed wiring board (1A) obtained by further adding layers to wiring board 1 with a built-in electronic component shown in FIG. 1. A brief description of the steps for manufacturing buildup multilayer printed wiring board (1A) is provided below.

Interlayer insulation layers (601, 602) are respectively formed on the upper and lower surfaces of wiring board 1 with a built-in electronic component. Through holes are formed in interlayer insulation layers (601, 602) to reach conductive patterns (8, 9) formed in wiring board 1 with a built-in electronic component.

Conductive patterns (603, 604) are respectively formed on interlayer insulation layers (601, 602). At the same time, via conductors (605, 606) are formed respectively in the through holes formed in interlayer insulation layers (601, 602). Accordingly, conductive patterns 603 and conductive patterns 8 are electrically connected. Also, conductive patterns 604 and conductive patterns 9 are electrically connected.

In the same manner, interlayer insulation layers (607, 608), conductive patterns (609, 610) and via conductors (611, 612) are formed.

Liquid-type or dry-film-type photosensitive resist (solder resist) is either applied or laminated on both main surfaces of the substrate. Then, mask film with a predetermined pattern is adhered to the surface of the photosensitive resist. The photosensitive resist is exposed to ultraviolet rays and developed using an alkaline solution.

Accordingly, solder-resist layers (613, 614) are formed, having opening portions to expose portions of conductive patterns (609, 610) which become solder pads. Through the above steps, buildup multilayer printed wiring board (1A) shown in FIG. 16 is completed.

In the present embodiment, wiring board 1 with a built-in electronic component was manufactured using a face-up method in which electronic component 3 is accommodated in cavity 21 so that terminals 30 are positioned on the upper side as shown in FIG. 8. However, the present embodiment is not limited to such. Wiring board 1 with a built-in electronic component may also be manufactured using a face-down method in which electronic component 3 is accommodated in cavity 21 so that terminals 30 are positioned on the lower side.

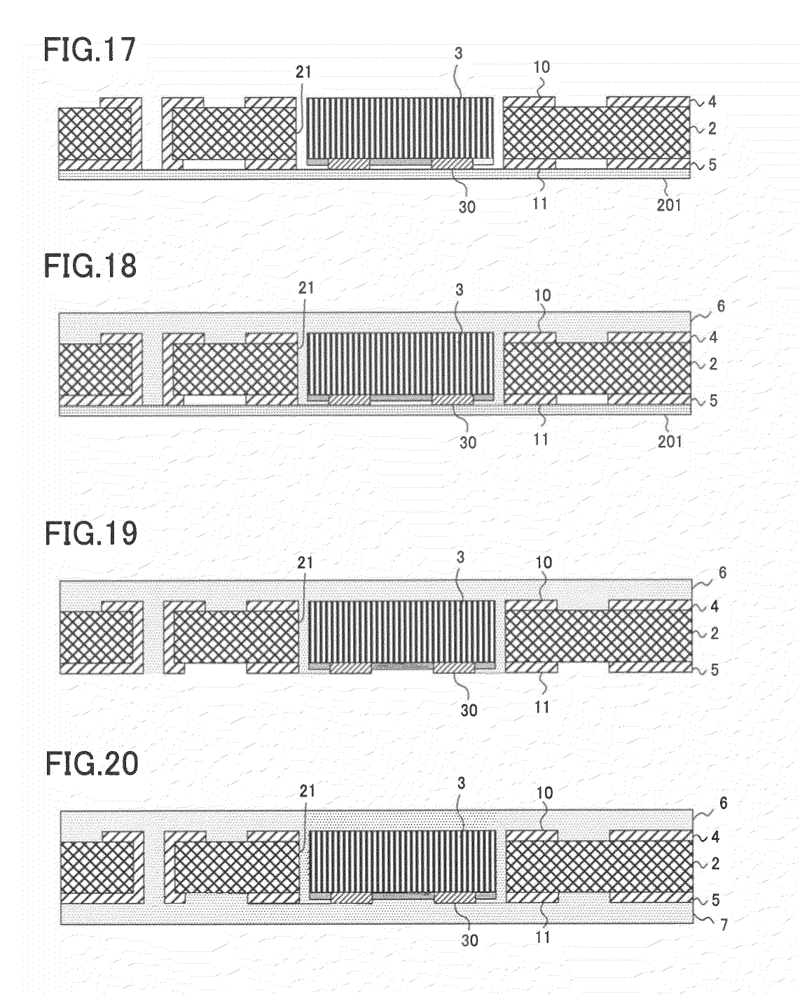

In such a case, after tape 201 is laminated on the lower-surface side of substrate 2 as shown in FIG. 7, electronic component 3 is positioned on the upper surface of tape 201 in such a way that terminals 30 are positioned on the lower side as shown in FIG. 17.

As shown in FIG. 18, film-type prepreg with an approximate thickness of 60 μm is laminated on the upper surface of substrate 2 using a vacuum lamination method. Accordingly, interlayer insulation layer 6 is formed.

As shown in FIG. 19, tape 201 is removed by irradiating ultraviolet rays at tape 201. As shown in FIG. 20, film-type prepreg is laminated on the lower surface of substrate 2 by a vacuum lamination method. Accordingly, interlayer insulation layer 7 is formed on the lower surface of substrate 2.

Using a carbon dioxide gas (CO2) laser, a UV-YAG laser or the like, via holes are formed in interlayer insulation layers (6, 7). Conductive patterns (8, 9) and via conductors (60, 70) are formed by an additive method, for example.

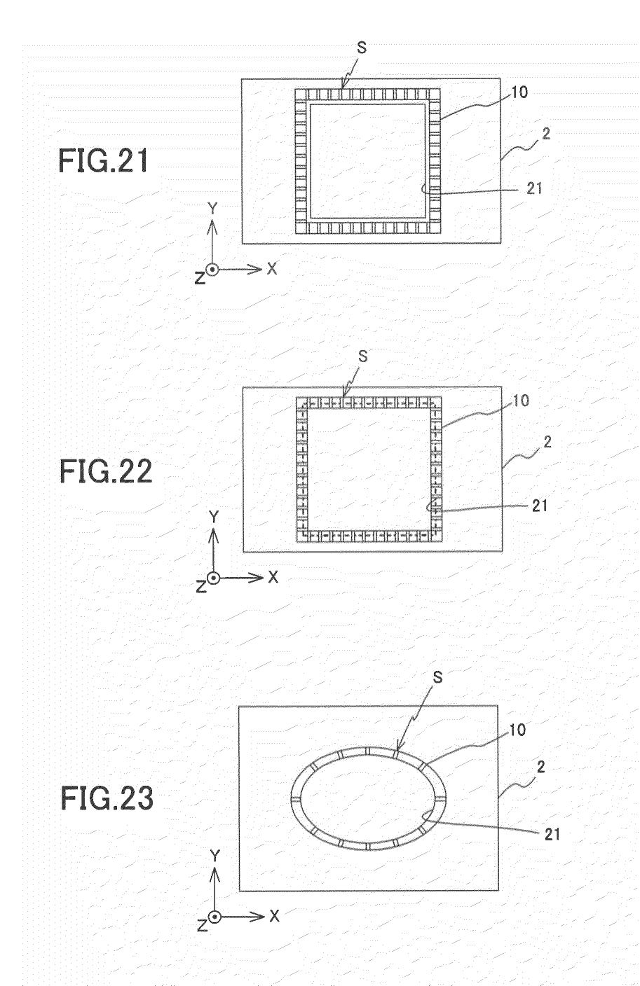

In each of the above embodiments, conductive pattern 10 is formed along the periphery of cavity 21 as shown in FIG. 14, and an inner side surface of conductive pattern 10 and an inner-wall surface of cavity 21 are positioned on the same plane. However, that is not the only option, and conductive pattern 10 may also be formed in such a way that the inner side surfaces of conductive pattern 10 are positioned away from cavity 21 as shown in FIG. 21. In such a case, the distance is preferred to be 50 μm or less between the inner side surfaces of conductive pattern 10 and the inner-wall surfaces of cavity 21.

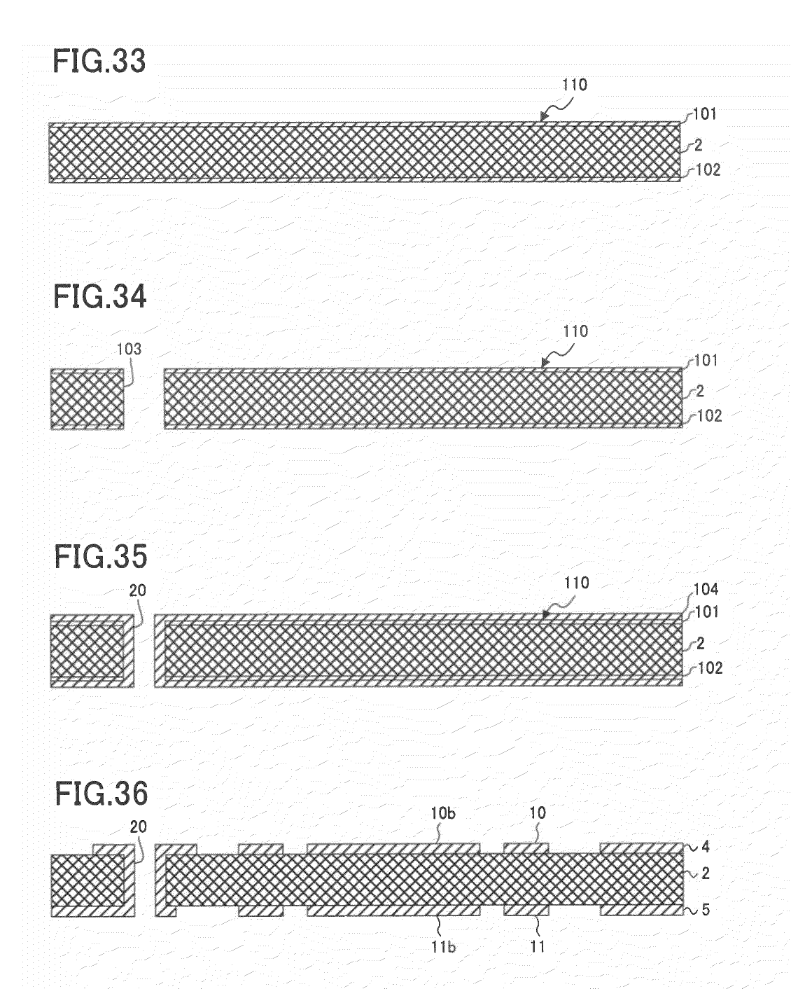

In the following, a method for manufacturing wiring board 1 with a built-in electronic component having conductive pattern 10 as shown in FIG. 21 is described with reference to FIGS. 33 through 38.

As shown in FIG. 33, copper-clad laminate 110 is prepared, being made of substrate 2 with an approximate thickness of 110 μm and copper foils (101, 102) laminated on the surfaces of substrate 2 to be approximately 12 μm thick.

Through holes 103 are formed in copper-clad laminate 110 using a drill or the like as shown in FIG. 34. Desmearing is performed. Accordingly, smearing or the like remaining on the inner surfaces of through holes 103 is removed.

Electroless copper plating and electrolytic copper plating are performed on copper-clad laminate 110. Accordingly, copper-plated film 104 is formed on the surfaces of copper-clad laminate 110 and on the inner-wall surfaces of through holes 103 as shown in FIG. 35. Copper-plated film 104 formed on the inner-wall surfaces of through holes 103 becomes through-hole conductors 20.

Using a subtractive method, for example, copper foils (101, 102) and copper-plated film 104 on the surfaces of substrate 2 are patterned to form conductive patterns (10, 11) shaped as rectangular frames and rectangular conductive patterns (10b, 10a) surrounded by conductive patterns (10, 11) as shown in FIG. 36.

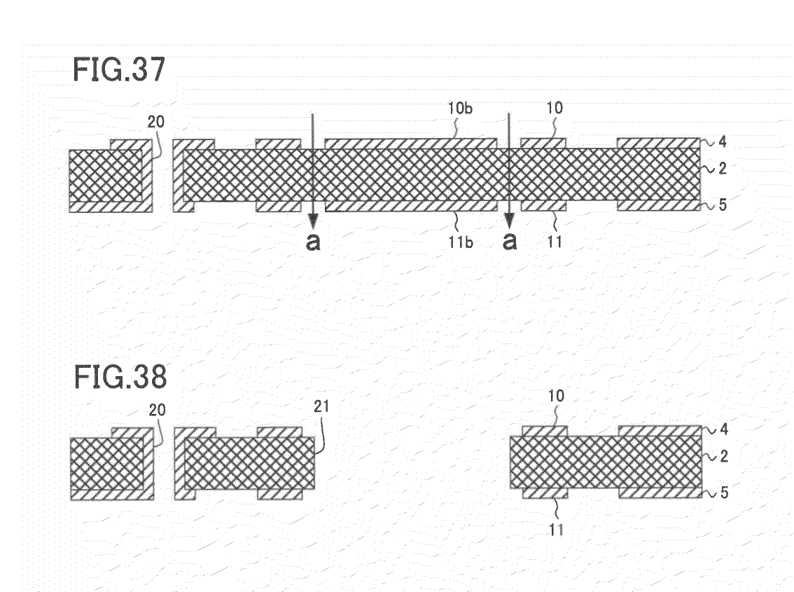

As shown by arrows “a” in FIG. 37, laser light is irradiated at the space between conductive pattern 10 and conductive pattern (10b) while the laser light moves along the periphery of conductive pattern (10b) so that substrate 2 is cut along the periphery of conductive pattern (10b). Accordingly, cavity 21 is formed in the portion surrounded by conductive pattern 10 as shown in FIG. 38.

In the following, after slits are formed in conductive pattern 10 through the process described above and an electronic component is accommodated in cavity 21, insulation layers and conductive patterns are built up. Accordingly, wiring board 1 with a built-in electronic component is completed.

In such wiring board 1 with a built-in electronic component, part of the resin outside conductive pattern 10 also moves to the portion surrounded by conductive pattern 10 through slits “S” formed in conductive pattern 10 while film-type prepreg is laminated. Therefore, the thickness of interlayer insulation layer 6 is made uniform near the periphery of cavity 21. Accordingly, the upper surface of interlayer insulation layer 6 is made flat, enabling precise buildup of multiple conductive patterns and multiple interlayer insulation layers on substrate 2. However, in such a case, the distance from the inner-wall surfaces of cavity 21 to the inner-wall surfaces of conductive pattern 10 is preferred to be shorter than the line width of conductive pattern 10.

As shown in FIG. 22, conductive pattern 10 may protrude slightly over cavity 21 (inner side). To form conductive pattern 10 in a shape shown in FIG. 22, slightly complex procedures are required compared with the above embodiment. However, interlayer insulation layer 6 is effectively prevented from being recessed near the periphery of cavity 21.

In the above embodiment, an example in which cavity 21 is shaped as a square is described. However, that is not the only option, and cavity 21 may also be a circle or an ellipse as shown in FIG. 23, for example. In addition, conductive pattern 10 formed to surround cavity 21 may also be shaped as a circle, an ellipse or a polygon.

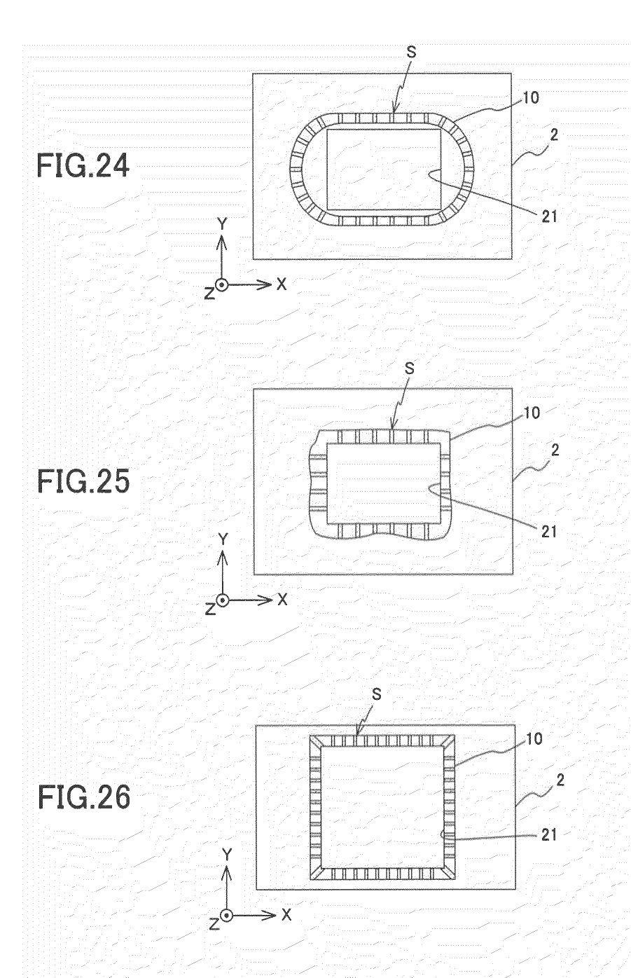

The shape of conductive pattern 10 is not always required to be the same shape as cavity 21. For example, as shown in FIG. 24, elliptical conductive pattern 10 may be formed to surround rectangular cavity 21. Also, the line width of conductive pattern 10 may be irregular as shown in FIG. 25.

In the above embodiment, slits “S” formed in conductive pattern 10 were formed by etching. However, that is not the only option. Slits “S” may also be formed by performing laser etching at conductive pattern (10a) or conductive pattern 10.

Slits “S” formed in conductive pattern 10 may also be formed in the corners of conductive pattern 10 as shown in FIG. 26. When cavity 21 is rectangular, resin may occasionally not be filled sufficiently in the vicinity of the four corners of electronic component 3. Slits “S” formed in the corners of conductive pattern 10 allow resin to flow sufficiently into the vicinity of the four corners of electronic component 3.

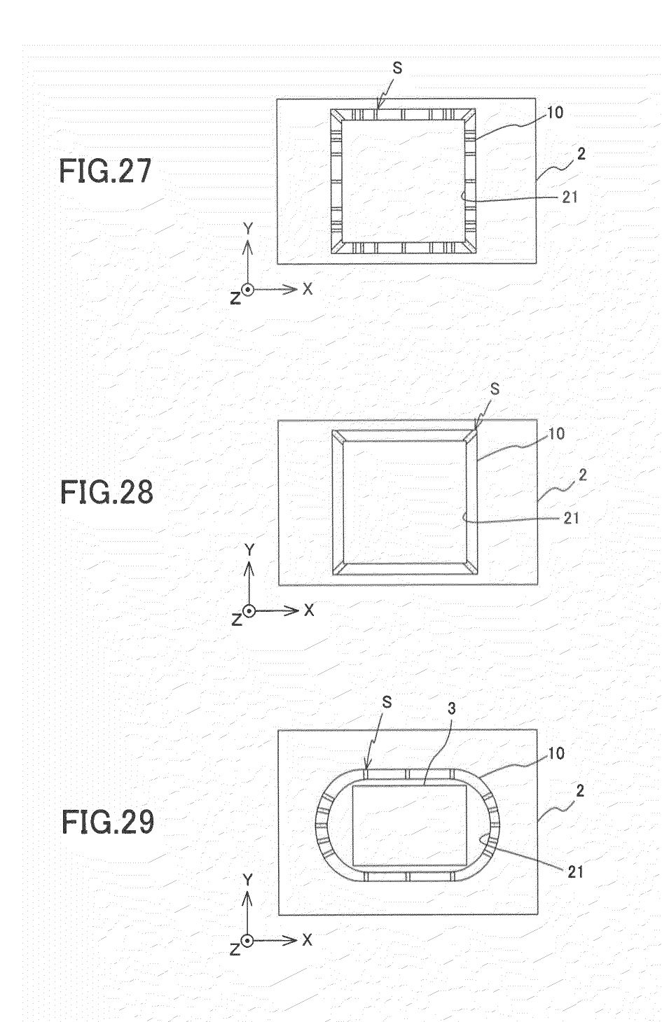

In the above embodiment, slits “S” are formed in the entire conductive pattern 10. However, that is not the only option, and slits “S” may be formed preferentially in locations near the corners of conductive pattern 10 as shown in FIG. 27, for example. Alternatively, slits “S” may be formed only in the corners of conductive pattern 10 as shown in FIG. 28. Accordingly, resin flows sufficiently into the vicinity of the four corners of electronic component 3.

When conductive pattern 10 is formed along the periphery of circular or elliptical cavity 21, slits “S” may be formed preferentially in portions farther from electronic component 3 as shown in FIG. 29, for example.

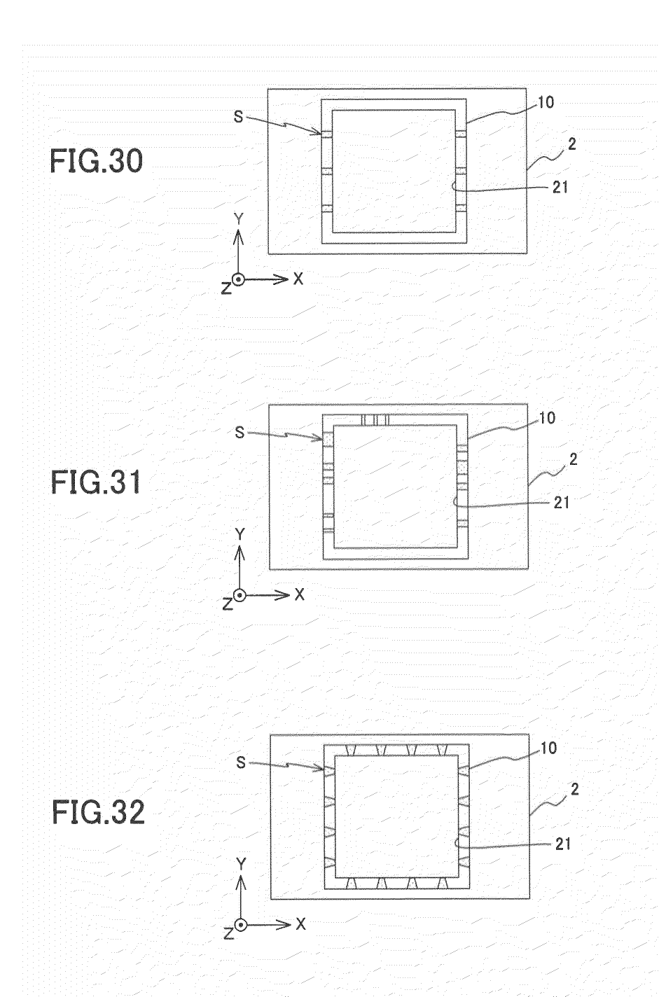

In the above embodiment, slits “S” are formed along conductive pattern 10 at regular intervals. However, that is not the only option, and as shown in FIG. 30, for example, slits “S” may be formed only on both sides of cavity 21, such as on the (−X) side and (+X) side of cavity 21. Alternatively, as shown in FIG. 31, for example, slits “S” may be formed in conductive pattern 10 at an irregular pitch.

As shown in FIG. 32, for example, slits “S” may also be formed with a width decreasing from the outer side of conductive pattern 10 toward the inner side.

Slits “S” may be formed to extend from the upper surface of conductive pattern 10 to the lower surface. Alternatively, slits “S” may be formed to reach an appropriate depth from the upper surface of conductive pattern 10.

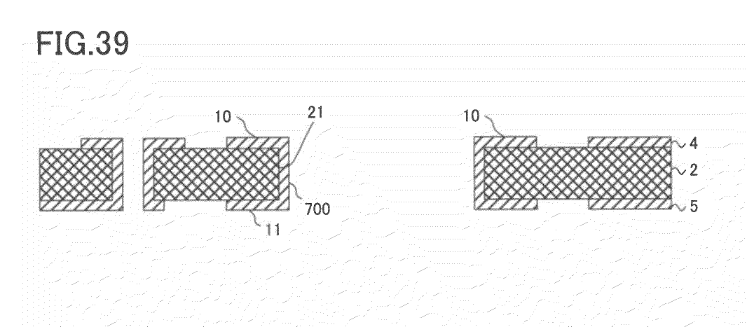

As shown in FIG. 39, for example, conductive pattern 10 and conductive pattern 11 may be electrically connected through copper-plated film 700 formed on the inner-wall surfaces of cavity 21. Copper-plated film 700 may be used, for example, to shield electronic component 3 accommodated in cavity 21.

In the above embodiment, conductive patterns (10, 11) were set as dummy patterns which are not electrically connected to other conductive patterns. However, conductive patterns (10, 11) are not limited to such, and they may also be electrically connected to other conductive patterns (4, 5). By doing so, they may form part of electronic circuits. Alternatively, they may be used as ground conductors.

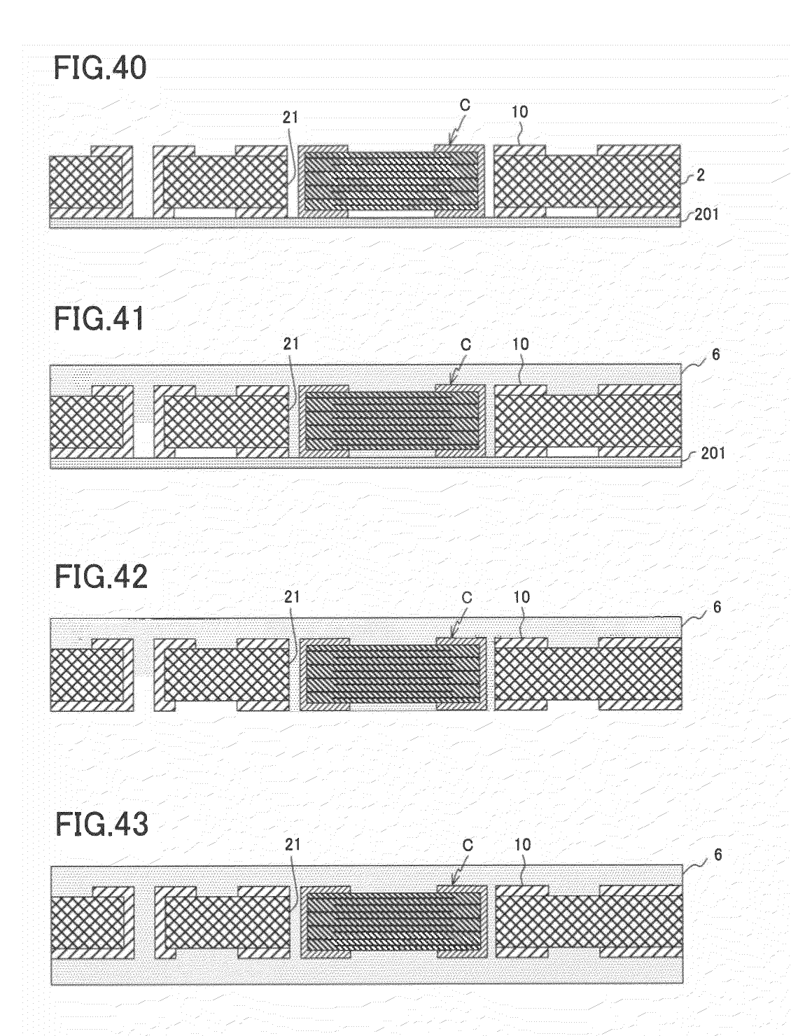

Electronic component 3 accommodated in substrate 2 is not limited to semiconductor elements such as an IC chip. For example, as shown in FIGS. 40 through 43, capacitor “C” may be accommodated in substrate 2 through the same procedures as in the above embodiment.

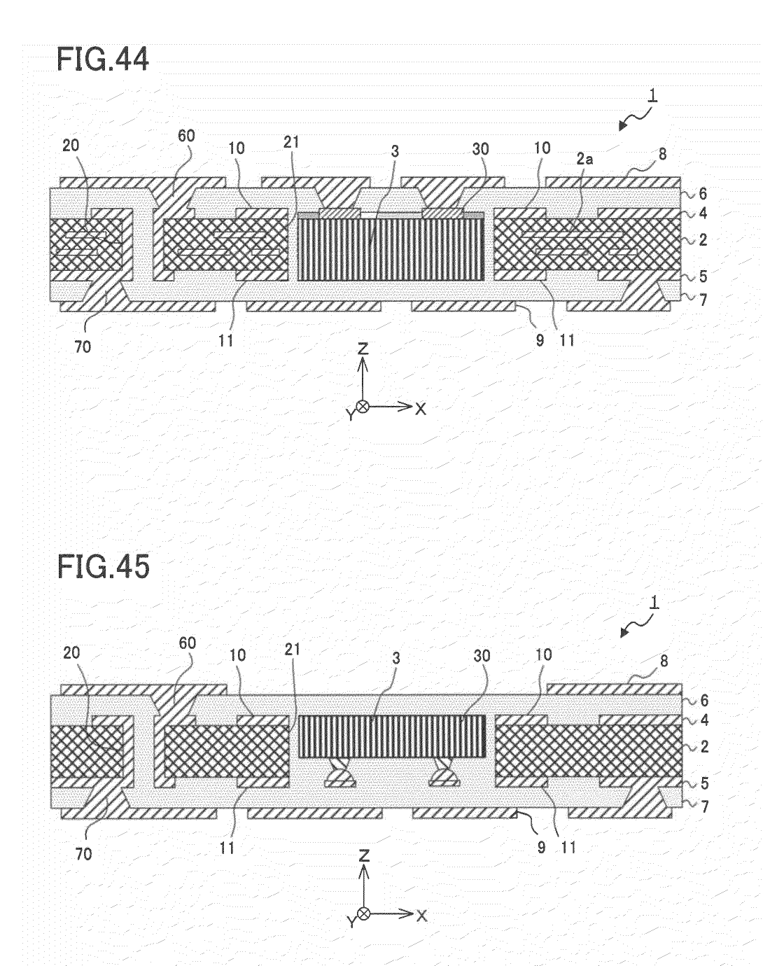

In the above embodiment, substrate 2 was a substrate made by impregnating reinforcement material (base material) such as glass cloth, glass non-woven fabric, aramid non-woven fabric or the like with epoxy resin, BT (bismaleimide triazine) resin, polyimide resin or the like. However, substrate 2 where cavity 21 is to be formed is not limited to such, and may also be a substrate where conductive patterns (2a) are formed inside as shown in FIG. 44.

In cavity 21 formed in substrate 2, a component to be flip-chip mounted may be accommodated as electronic component 3 as shown in FIG. 45. In such a case as well, when interlayer insulation layer 6 is formed by laminating film-type prepreg on the upper surface of substrate 2, resin mainly from the prepreg positioned above electronic component 3 flows into the space in cavity 21 between electronic component 3 and inner walls of substrate 2. Then, part of the resin outside conductive pattern 10 moves to the portion surrounded by conductive pattern 10 through slits “S” formed in conductive pattern 10. Accordingly, the thickness of interlayer insulation layer 6 is made uniform near the periphery of cavity 21.

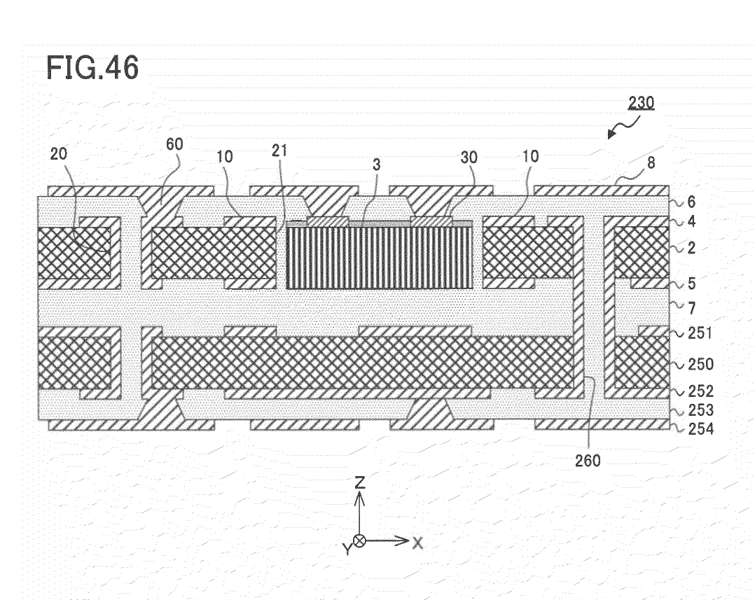

Also, electronic component 3 may be accommodated in cavity 21 formed in a substrate of a laminated wiring board. For example, FIG. 46 is a view showing laminated wiring board 230 having substrate 2 and substrate 250. Laminated wiring board 230 as shown in FIG. 46 is manufactured as follows: substrate 2 with built-in electronic component 3 and having conductive patterns (4, 5) and substrate 250 having conductive patterns (251, 252) are integrated by interlayer insulation layer 7; and interlayer insulation layers (6, 253) are formed while through-hole conductors 260 and the like are formed to electrically connect conductive patterns (8, 254) and conductive patterns formed in substrates (2, 250).

In the above embodiment, when interlayer insulation layer 6 is formed, the space between electronic component 3 and the inner walls of cavity 21 is filled with resin material that forms interlayer insulation layer 6. Accordingly, electronic component 3 is fixed. However, that is not the only method, and electronic component 3 may be fixed to substrate 2 using another method. For example, before interlayer insulation layer 6 is formed, insulative resin made of thermosetting resin and inorganic filler, for example, is filled in the space between electronic component 3 and the inner walls of substrate 2 so that electronic component 3 is fixed to substrate 2.

In the above embodiment, conductive pattern 11 is formed on the lower surface of substrate 2. However, that is not the only option, and conductive pattern 11 is not always required to be formed.

In the above embodiment, through holes 103 were formed in substrate 2 using a drill or the like. However, that is not the only option. Through holes may also be formed using a carbon dioxide gas (CO2) laser, an Nd-YAG laser, an excimer laser or the like.

In the above embodiment, cavity 21 to accommodate electronic component 3 was formed in substrate 2 using a drill or the like. However, that is not the only option. Cavity 21 may also be formed using a carbon dioxide gas (CO2) laser, an Nd-YAG laser, an excimer laser or the like.

In the present embodiment, cavity 21 was set to be a hole that penetrates through substrate 2. However, cavity 21 is not limited to such, and may also be a recessed portion which opens only upward.

A wiring board according to an embodiment of the present invention has the following: a substrate in which a cavity is formed; an electronic component accommodated in the cavity; a first conductive pattern formed on a first surface of the substrate to surround an opening of the cavity; a second conductive pattern formed around the first conductive pattern; and an insulation layer formed on the first surface to cover the first conductive pattern, the second conductive pattern and the opening of the cavity. In the first conductive pattern, a slit is formed to extend from the side having the second conductive pattern to the side having the opening of the cavity.

A method for manufacturing a wiring board according to another embodiment of the present invention includes the following: in a substrate, forming a cavity to accommodate the electronic component; on a first surface of the substrate, forming a first conductive pattern in which a slit is formed and which surrounds an opening of the cavity, and forming a second conductive pattern to be positioned around the first conductive pattern; and on the first surface, forming an insulation layer to cover the first conductive pattern, the second conductive pattern and the opening of the cavity. The slit extends from the side having the first conductive pattern to the side having the opening of the cavity.

A first conductive pattern is formed on an upper surface of a substrate to surround an opening of a cavity. Accordingly, considerable warping of an insulation layer is suppressed. Also, slits are formed in the first conductive pattern to extend from the side having a second conductive pattern to the side having the opening of the cavity. Therefore, when the insulation layer is formed, part of the resin outside the first conductive pattern moves through the slits to the portion surrounded by first conductive pattern 10. Accordingly, thicknesses of the insulation layer become equal in the portion surrounded by the first conductive pattern and in the portion outside the first conductive pattern, leading to a flat insulation layer. As a result, reliability of the wiring board is enhanced.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a substrate having a cavity;
an electronic component accommodated in the cavity of the substrate;
a first conductive pattern formed on a first surface of the substrate and having a frame shape surrounding an opening of the cavity;
a second conductive pattern formed on the first surface of the substrate and outside the frame shape of the first conductive pattern; and
an insulation layer formed on the first surface of the substrate and covering the first conductive pattern, the second conductive pattern and the opening of the cavity,
wherein the first conductive pattern has at least one slit extending from an outside of the frame shape to an inside of the frame shape.

2. The wiring board according to claim 1, wherein the cavity has a space between the electronic component and an inner wall of the cavity, and the space in the cavity is filled with a resin flowed out of the insulation layer.

3. The wiring board according to claim 1, wherein the first conductive pattern has a thickness which is substantially equal to a thickness of the second conductive pattern.

4. The wiring board according to claim 1, wherein the frame shape of the first conductive pattern is substantially same as a peripheral shape of the opening of the cavity.

5. The wiring board according to claim 4, wherein the slit is formed in the conductive pattern at a farthest position from the electronic component.

6. The wiring board according to claim 1, wherein the opening of the cavity has a rectangular shape, and the slit is formed in a corner portion of the rectangular shape of the opening.

7. The wiring board according to claim 1, wherein the first conductive pattern has a side wall which is formed on a substantially same plane as an inner wall of the cavity formed in the substrate.

8. The wiring board according to claim 1, wherein the cavity has an inner wall which is positioned inside the frame shape of the first conductive pattern.

9. The wiring board according to claim 1, further comprising a third conductive pattern formed on a second surface on an opposite side of the first surface of the substrate, wherein the cavity is a hole penetrating through the substrate, and the third conductive pattern is surrounding an opening of the cavity on the second surface.

10. The wiring board according to claim 1, wherein the substrate has a thickness which is substantially equal to a thickness of the electronic component.

11. The wiring board according to claim 1, wherein the electronic component is accommodated in the cavity of the substrate such that the first surface of the substrate and a terminal of the electronic component are on a substantially same plane.

12. The wiring board according to claim 1, wherein the at least one slit of the first conductive pattern comprises a plurality of slits extending from the outside of the frame shape to the inside of the frame shape.

13. A method for manufacturing a wiring board, comprising:
forming in a substrate a cavity which accommodates an electronic component;
forming on a first surface of the substrate a first conductive pattern having a frame shape surrounding an opening of the cavity and at least one slit extending from an outside of the frame shape to an inside of the frame shape;
forming a second conductive pattern on the first surface of the substrate outside the frame shape of the first conductive pattern;
accommodating in the cavity of the substrate an electronic component; and
forming on the first surface an insulation layer covering the first conductive pattern, the second conductive pattern and the opening of the cavity.

14. The method for manufacturing a wiring board according to claim 13, wherein the forming of the insulation layer comprises filling a resin to flow out from the insulation layer into a space between the electronic component and the cavity.

15. The method for manufacturing a wiring board according to claim 13, wherein the first conductive pattern and the second conductive pattern are formed to have a same thickness.

16. The method for manufacturing a wiring board according to claim 13, wherein the frame shape of the first conductive pattern is formed to be shaped similar to a shape of the opening of the cavity.

17. The method for manufacturing a wiring board according to claim 16, wherein the slit is formed in the first conductive pattern at a location farthest from the electronic component.

18. The method for manufacturing a wiring board according to claim 13, wherein the cavity is formed such that the opening of the cavity is shaped to be a rectangular shape, and the slit is formed in a corner portion of the rectangular shape of the opening of the cavity.

19. The method for manufacturing a wiring board according to claim 13, wherein the first conductive pattern is formed such that a side wall of the first conductive pattern and an inner wall of the cavity formed in the substrate are positioned on a substantially same plane.

20. The method for manufacturing a wiring board according to claim 13, wherein the first conductive pattern is formed such that an inner wall of the cavity formed in the substrate is positioned inside the first conductive pattern.

21. The method for manufacturing a wiring board according to claim 13, further comprising forming a third conductive pattern on a second surface on an opposite side of the first surface of the substrate such that the third conductive pattern surrounds an opening of the cavity on the second surface of the substrate, wherein the cavity is penetrating through the substrate.

22. The method for manufacturing a wiring board according to claim 13, wherein the electronic component has a thickness substantially equal to a thickness of the substrate.

23. The method for manufacturing a wiring board according to claim 13, wherein the forming of the first conductive pattern comprises forming the slit in a plurality.

24. The method for manufacturing a wiring board according to claim 13, wherein the accommodating the electronic component comprises positioning in the cavity of the substrate the electronic component such that the first surface of the substrate and a terminal of the electronic component are on a substantially same plane.
